(19) United States
(12) Patent Application Publication
(10) Pub. No.: US 2026/0260850 A1
(43) Pub. Date: Sep. 3, 2026

(54) ELECTROSTATIC CHUCK ASSEMBLY

(71) Applicant: NGK Corporation, Nagoya-shi (JP)

(72) Inventors: Taro USAMI, Ginan-town (JP); Tatsuya KUNO, Nagoya-city (JP); Yutaka UNNO, Handa-city (JP); Kanta MIYAMOTO, Handa-city (JP)

(21) Appl. No.: 19/655,776

(22) Filed: Apr. 23, 2026

Related U.S. Application Data
(63) Continuation of application No. PCT/JP2025/033407, filed on Sep. 22, 2025.

(30) Foreign Application Priority Data
Nov. 7, 2024 (JP) 2024-195499

(51) Int. Cl. H01J 37/32; H10P 72/72; H10P 72/00

(52) U.S. Cl. CPC H01J 37/3244; H01J 37/32082; H01J 37/32467; H01J 37/32568; H01J 37/32724; H10P 72/722; H01J 2237/2007; H01J 2237/3341; H10P 72/0421

(57) ABSTRACT

There is provided an chuck assembly including: a ceramic plate having a top surface on which a wafer is to be placed and a bottom surface facing the top surface and incorporating an internal electrode that is an ESC electrode and/or an RF electrode; a cooling plate mounted to the bottom surface of the ceramic plate; a plug placement hole penetrating the ceramic plate from the bottom surface to the top surface; a gas passage plug press-fitted into the plug placement hole and configured to allow gas to pass therethrough; and a gas introduction passage provided in the cooling plate and communicating with the plug placement hole. A side surface of at least one of the gas passage plug and the plug placement hole is composed of a low secondary electron emission coefficient (SEEC) material having an SEEC of 5.0 or lower.

### CROSS-REFERENCE TO RELATED APPLICATIONS

This application is a continuation application of PCT/JP2025/033407 filed September 22, 2025, which claims priority to Japanese Patent Application No. 2024-195499 filed November 7, 2024, the entire contents all of which are incorporated herein by reference.

### BACKGROUND OF THE INVENTION

### 1. Field of the Invention

The present disclosure relates to an electrostatic chuck assembly.

### 2. Description of the Related Art

Circuit formation in semiconductor device manufacturing is generally performed by plasma etching. Plasma etching is performed by introducing an inert gas into a vacuum chamber of a plasma etching apparatus and ionizing the inert gas into plasma. An electrostatic chuck assembly that functions as a susceptor on which a wafer to be etched is placed is provided in the plasma etching apparatus. The electrostatic chuck assembly includes an electrode-embedded ceramic plate that functions as an electrostatic chuck and a cooling plate that supports a bottom surface of the electrode-embedded ceramic plate. The wafer is fixed to the electrostatic chuck assembly by being electrostatically attracted to the electrode-embedded ceramic plate, and subjected to plasma etching in this state. On the other hand, the cooling plate is provided on a bottom surface of the electrode-embedded ceramic plate and is configured to dissipate heat generated on the wafer by plasma etching.

In recent years, plasma etching apparatuses have been increasingly upgraded to higher power levels to enable deep etching. In plasma etching apparatuses, a wafer is placed on an electrode-embedded ceramic plate of an electrostatic chuck assembly in order to cool and retain the shape of the wafer. In such an application as an electrostatic chuck, a gas is introduced between the wafer and the ceramic plate to increase efficiency of thermal conduction between the wafer and the ceramic plate and to reduce a contact area and suppress particle generation. In order to supply the gas, the ceramic plate is provided with a gas hole. FIG. 5 shows an example of such a conventional electrostatic chuck assembly. A conventional electrostatic chuck assembly 110 shown in FIG. 5 includes a ceramic plate 112, a cooling plate 114 mounted to the ceramic plate 112 via a bonding layer 113, a gas inlet hole 115 that penetrates the ceramic plate 112 and the cooling plate 114, and an insulating tube 117 that covers surfaces facing the gas inlet hole 115 of the bonding layer 113 and the cooling plate 114. In such a configuration, when radio frequency waves (RF) are applied to a wafer W placed on the ceramic plate 112, although the process gas above the wafer W should be ionized into plasma, plasma P caused by abnormal discharge unintentionally occurs within the gas inlet hole 115 due to effects of recent trends such as higher frequencies.

To address such problems, a method has been proposed to prevent abnormal discharge by placing a plug in a through-hole corresponding to the gas inlet hole 115. For example, Patent Literature 1 (JP2024-88883A) discloses a plug body formed from a dense ceramic material and a plug which is provided within the plug body and which includes a helical gas flow path extending from a bottom surface to a top surface of the plug body. The plug body is formed from a dense ceramic material and is therefore referred to as a dense plug. On the other hand, porous plugs are also known. Patent Literature 2 (JP7514815B) discloses a member for a semiconductor manufacturing apparatus, including: a ceramic plate; a conductive substrate provided on a bottom surface of the ceramic plate; a first hole penetrating the ceramic plate in an up-down direction; a second hole penetrating the conductive substrate in the up-down direction and communicating with the first hole; and a porous plug of which a top surface is exposed in an upper opening of the first hole and of which a bottom surface is positioned at a same height or below a top surface of the conductive substrate.

### CITATION LIST

### PATENT LITERATURE

Patent Literature 1: JP2024-88883A

Patent Literature 2: JP7514815B

### NON-PATENT LITERATURE

Non-Patent Literature 1: Sawa Araki, "Secondary Electron Emission Coefficient Measurement Technique with Scanning Auger Microprobe", Journal of Surface Analysis, Vol.11, No.2 (2004), pp.71-76

### SUMMARY OF THE INVENTION

The dense plug is arranged in the through-hole of the ceramic plate by press-fitting. FIG. 6 shows an example of a structure in which a dense plug is fixed by press-fitting. An electrostatic chuck assembly 110' shown in FIG. 6 includes: a ceramic plate 112; a cooling plate 114 mounted to the ceramic plate 112 via a bonding layer 113; a plug placement hole 116 that penetrates the ceramic plate 112 and the bonding layer 113; a gas passage plug 118 such as a dense plug that has been press-fitted into the plug placement hole 116; and a gas introduction passage 120 that is provided in the cooling plate 114 and communicates with the plug placement hole 116. According to such a configuration, while the generation of plasma in the hole is suppressed as compared to a plug-less configuration such as that shown in FIG. 5, a large potential difference between the wafer W and the cooling plate 114 may cause a creeping discharge D to occur along an interface between the gas passage plug 118 and the ceramic plate 112.

The present inventors have recently discovered that by constructing a side surface of at least one of the gas passage plug and the plug placement hole with a low secondary electron emission coefficient (SEEC) material having an SEEC of 5.0 or lower, an electrostatic chuck assembly can be provided in which a creeping discharge is less likely to occur at the interface between the gas passage plug and the ceramic plate.

Accordingly, an object of the present invention is to provide an electrostatic chuck assembly including a gas passage plug, in which a creeping discharge is less likely to occur at an interface between the gas passage plug and a ceramic plate.

The present disclosure provides the following aspects:

### Aspect 1

An electrostatic chuck assembly, comprising:

a ceramic plate having a top surface on which a wafer is to be placed and a bottom surface facing the top surface and incorporating an internal electrode that is an ESC electrode and/or an RF electrode;

a cooling plate mounted to the bottom surface of the ceramic plate;

a plug placement hole penetrating the ceramic plate from the bottom surface to the top surface;

a gas passage plug press-fitted into the plug placement hole and configured to allow gas to pass therethrough; and

a gas introduction passage provided in the cooling plate and communicating with the plug placement hole,

wherein a side surface of at least one of the gas passage plug and the plug placement hole is composed of a low secondary electron emission coefficient (SEEC) material having an SEEC of 5.0 or lower.

### Aspect 2

The electrostatic chuck assembly according to aspect 1, wherein the secondary electron emission coefficient (SEEC) is 2.0 or lower.

### Aspect 3

The electrostatic chuck assembly according to aspect 1 or 2, wherein the low-SEEC material includes at least one selected from the group consisting of TiN, Al, brass, SiO₂, and Cr₂O₃.

### Aspect 4

The electrostatic chuck assembly according to any one of aspects 1 to 3, wherein a side surface of at least one of the gas passage plug and the plug placement hole includes a coating film and/or a surface modification film of the low-SEEC material.

### Aspect 5

The electrostatic chuck assembly according to any one of aspects 1 to 4, wherein at least one of a top surface and a bottom surface of the gas passage plug is composed of the low-SEEC material.

### Aspect 6

The electrostatic chuck assembly according to aspect 5, wherein at least one of the top surface and the bottom surface of the gas passage plug includes a coating film and/or a surface modification film of the low-SEEC material.

### Aspect 7

The electrostatic chuck assembly according to any one of aspects 1 to 6, wherein an interface between the plug placement hole and the gas passage plug is free of an adhesive.

### Aspect 8

The electrostatic chuck assembly according to any one of aspects 1 to 6, wherein an adhesive is partially present between the plug placement hole and the gas passage plug, and a portion which is free of the adhesive on a side surface of at least one of the gas passage plug and the plug placement hole is composed of the low-SEEC material.

### Aspect 9

The electrostatic chuck assembly according to any one of aspects 1 to 8, wherein the gas passage plug is composed of a dense body having an internal gas flow path.

### Aspect 10

The electrostatic chuck assembly according to any one of aspects 1 to 8, wherein the gas passage plug is composed of a porous body.

### Aspect 11

The electrostatic chuck assembly according to any one of aspects 1 to 10, further comprising, in the gas introduction passage, a conductive gas passage portion in contact with a bottom surface of the gas passage plug, electrically connected to the cooling plate, and allowing passage of gas between the gas passage plug and the gas introduction passage.

### Aspect 12

The electrostatic chuck assembly according to aspect 11, wherein the conductive gas passage portion includes a leaf spring that biases the gas passage plug upward.

### BRIEF DESCRIPTION OF THE DRAWINGS

FIG. 1 is a schematic top view showing an example of an electrostatic chuck assembly according to the present invention.

FIG. 2 is a sectional view taken along line A-A of the electrostatic chuck assembly shown in FIG. 1.

FIG. 3 is a schematic sectional view showing an example of a gas passage plug and a ceramic plate (in particular, a plug placement hole) to which a low-SEEC material is applied.

FIG. 4 is a schematic sectional view showing an example of a gas passage plug to which a low-SEEC material is applied.

FIG. 5 is a schematic section view showing an example of a conventional electrostatic chuck assembly.

FIG. 6 is a schematic section view showing an example of an electrostatic chuck assembly not according to the present invention.

### DETAILED DESCRIPTION OF THE INVENTION

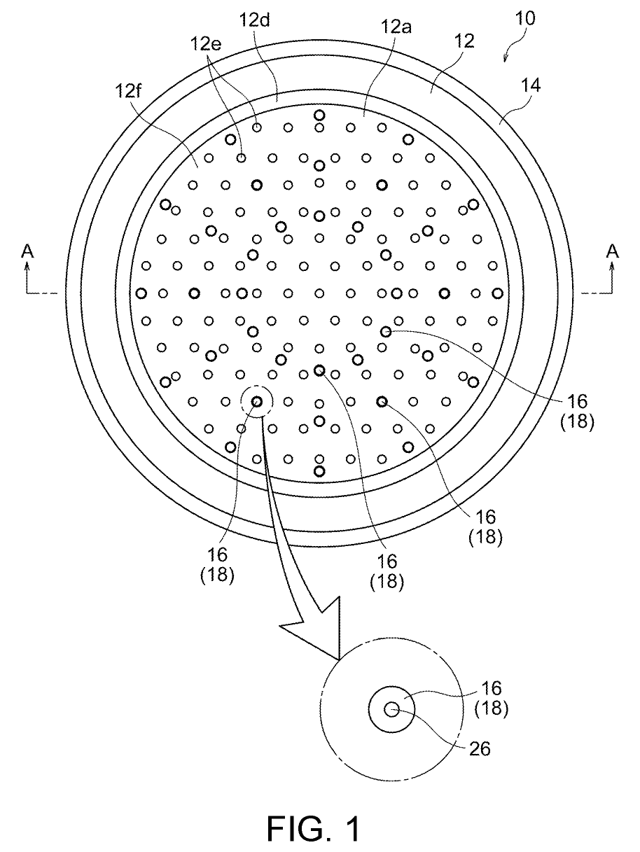

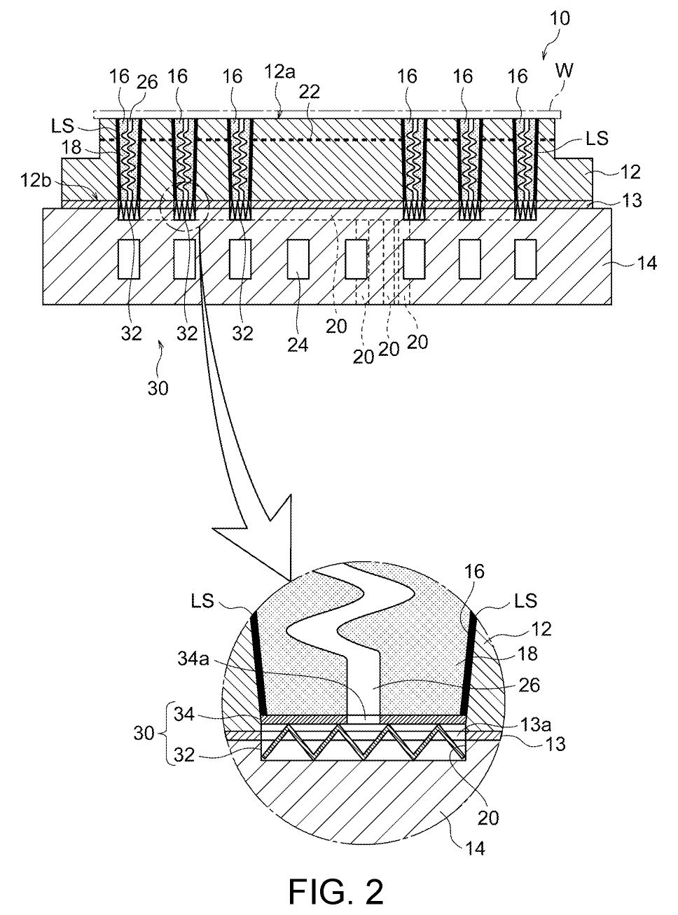

FIGS. 1 and 2 show an example of an electrostatic chuck assembly. An electrostatic chuck assembly 10 shown in FIGS. 1 and 2 includes a ceramic plate 12, a cooling plate 14, a plug placement hole 16, a gas passage plug 18, and a gas introduction passage 20. The ceramic plate 12 has a top surface 12a on which a wafer W is to be placed and a bottom surface 12b facing the top surface 12a. In addition, the ceramic plate 12 incorporates an internal electrode 22 that is an ESC electrode and/or an RF electrode. The cooling plate 14 is mounted to the bottom surface 12b of the ceramic plate 12. The plug placement hole 16 penetrates the ceramic plate 12 from the bottom surface 12b to the top surface 12a. The gas passage plug 18 is configured to allow gas to pass therethrough and is press-fitted into the plug placement hole 16. The gas introduction passage 20 is provided in the cooling plate 14 and communicates with the plug placement hole 16. In addition, a side surface of at least one of the gas passage plug 18 and the plug placement hole 16 is composed of a low secondary electron emission coefficient (SEEC) material LS having an SEEC of 5.0 or lower. By constructing the side surface of at least one of the gas passage plug 18 and the plug placement hole 16 with a low-SEEC material LS in this manner, an electrostatic chuck assembly 10 can be provided in which a creeping discharge is less likely to occur at an interface between the gas passage plug 18 and the ceramic plate 12.

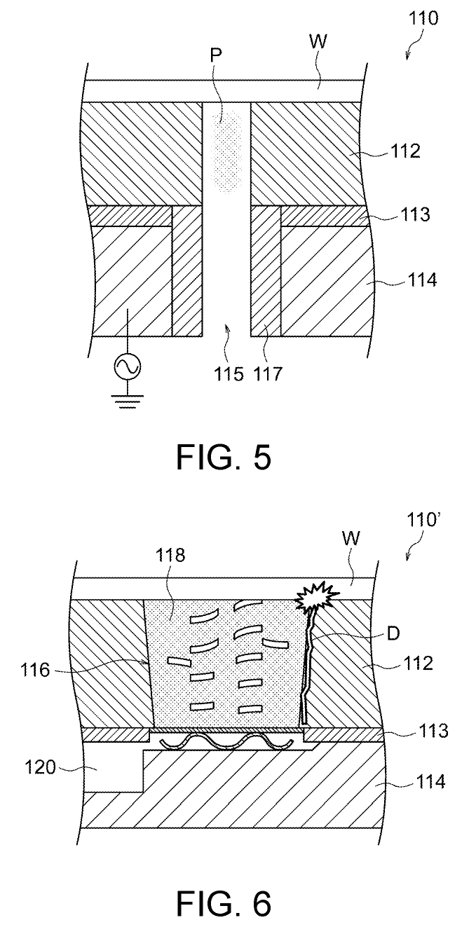

As described earlier, the dense plug is arranged in the through-hole of the ceramic plate by press-fitting. According to the electrostatic chuck assembly 110' shown in FIG. 6 that is configured in such a manner, while the generation of plasma in the hole is suppressed as compared to a plug-less configuration such as that shown in FIG. 5, a large potential difference between the wafer W and the cooling plate 114 may cause a creeping discharge D to occur along an interface between the gas passage plug 118 and the cooling plate 114. In this regard, since the gas passage plug 118 that is a dense plug or the like is typically fixed in the plug placement hole 116 by press-fitting, a slight gap exists at the interface between the gas passage plug 118 and the cooling plate 114 and, conceivably, the slight gap allows the creeping discharge D to occur. Specifically, in the case of fixation by press-fitting, unlike fixation achieved by direct baking of the ceramic constituting the plug or by applying an adhesive over an entire side surface of the plug, since it is impossible to completely seal the gap at the interface between the gas passage plug 118 and the cooling plate 114, a slight gap may form at this interface between the gas passage plug 118 and the cooling plate 114 and a creeping discharge attributable to the gap may occur. To address this problem, the present inventors focused on the secondary electron emission coefficient (SEEC). SEEC is an index defined as a ratio of the number of secondary electrons emitted from a sample to the number of electrons (primary electrons) incident on the sample. In addition, it was found that the creeping discharge described above is influenced by the SEEC, and since the greater the SEEC, the longer an electron avalanche persists, discharge voltage decreases and the creeping discharge D occurs as an abnormal discharge in a gas supply portion (in other words, the plug placement hole 116 to which the gas passage plug 118 has been fixed). Based on this finding, in the present invention, forming a side surface of at least one of the gas passage plug 18 and the plug placement hole 16 with a low-SEEC material LS having an SEEC of 5.0 or lower enables an occurrence of a creeping discharge at the interface between the gas passage plug 18 and the ceramic plate 12 to be suppressed. For example, in a case of a 2.5 mm-thick ceramic plate, a configuration capable of achieving a withstand voltage of 3 kV or higher under vacuum in a portion not filled with an adhesive of the gas supply portion can be realized.

The electrostatic chuck assembly 10 is used as a table on which the wafer is to be placed when subjecting the wafer W to CVD, etching, and the like using plasma, and is typically fixed in a vacuum chamber for manufacturing semiconductor devices.

The ceramic plate 12 may be of a configuration generally used as an electrostatic chuck. Therefore, the ceramic plate 12 incorporates an internal electrode 22 that is an ESC electrode (electrostatic electrode) and/or an RF electrode. A typical electrode-embedded ceramic plate 12 includes a disk-shaped ceramic base body and an internal electrode 22 embedded parallel to a top surface 12a or a bottom surface 12b at a predetermined height position in the ceramic base body. Examples of a ceramic material constituting the ceramic base body include aluminum nitride, silicon carbide, silicon nitride, and aluminum oxide. For example, the ceramic plate 12 may be a disk (for example, with a diameter of 300 mm and a thickness of 5 mm) made of a ceramic sintered compact such as an aluminum oxide sintered compact or an aluminum nitride sintered compact.

An annular sealing band 12d may be formed along an outer edge of the top surface 12a of the ceramic plate 12. A plurality of small circular protrusions 12e may be formed separated from each other over an entire inside region of the sealing band 12d. In this case, the sealing band 12d and the small circular protrusions 12e preferably have a same height and the height may be, for example, several μm to several tens of μm.

The internal electrode 22 can be a planar mesh electrode generally used as an ESC electrode or an RF electrode and may be connected to an external DC power supply via a power feeding member (not illustrated). A low-pass filter may be arranged along the power feeding member. The power feeding member is desirably electrically insulated from the cooling plate 14 and, if present, the conductive bonding layer 13. When a DC voltage is applied to the internal electrode 22, the wafer W is fixed by an electrostatic attraction force to the top surface 12a (specifically, a top surface of the sealing band 12d and top surfaces of the small circular protrusions 12e), and when the application of the DC voltage is removed, the wafer W is released from its attraction and fixation to the top surface 12a. Note that a portion of the top surface 12a in which the sealing band 12d and the small circular protrusions 12e are not provided will be referred to as a reference surface 12f.

The ceramic plate 12 may further incorporate a heater electrode. In this case, the heater electrode is fabricated from a conductive coil or a printed pattern and may be formed to extend from one end to another end across the entire ceramic plate 12 in a single continuous path in a plan view. The one end and the other end of the heater electrode may be connected to a pair of feeding rods (not illustrated) that penetrate the cooling plate 14 and the bonding layer 13 and inserted into the ceramic base body. The heater electrode may be configured so that a voltage is applied thereto via the feeding rods.

The cooling plate 14 is mounted to the bottom surface 12b of the ceramic plate 12. The cooling plate 14 may be a disk (a disk with a same diameter as or a larger diameter than the ceramic plate 12) with favorable thermal conductivity. A refrigerant flow path 24 through which a refrigerant circulates may be formed inside the cooling plate 14. The refrigerant that flows through the refrigerant flow path 24 is preferably a liquid and more preferably a liquid with electrical insulating properties. Examples of a liquid with electrical insulating properties include a fluorinated inert liquid. The refrigerant flow path 24 is formed to extend from one end (inlet) to another end (outlet) across the entire cooling plate 14 in a single path in a plan view. A supply port and a collection port of an external refrigerant apparatus (not illustrated) are connected to the one end and the other end of the refrigerant flow path 24, respectively. The refrigerant supplied to one end of the refrigerant flow path 24 from the supply port of the external refrigerant apparatus passes through the refrigerant flow path 24, returns to the collection port of the external refrigerant apparatus from the other end of the refrigerant flow path 24, and, after temperature adjustment, is once again supplied to the one end of the refrigerant flow path 24 from the supply port.

The cooling plate 14 may be made of a metallic material or a composite material of metal and ceramics. Examples of the metallic material include Al, Ti, Mo, and alloys thereof. Examples of the composite material of metal and ceramics include a metal matrix composite (MMC) and a ceramic matrix composite (CMC). Preferable examples of such composite materials include materials containing Si, SiC, and Ti (also referred to as SiSiCTi), materials in which Al and/or Si are impregnated into a SiC porous body, and composites of Al₂O₃ and TiC. The material constituting the cooling plate 14 should preferably be selected to have a thermal expansion coefficient close to that of the material constituting the ceramic plate 12 (in particular, the ceramic base body). Such a cooling plate 14 may be a conductive plate. Therefore, the cooling plate 14 can also be used as an RF electrode. In this case, an upper electrode (not illustrated) is arranged at a position separated upward from the ceramic plate 12 (in particular, the top surface 12a), and by applying high-frequency power between the upper electrode and the cooling plate 14 arranged parallel to each other, plasma can be generated.

The cooling plate 14 is preferably bonded to the bottom surface 12b of the ceramic plate 12 via the bonding layer 13. The bonding layer 13 may be a conductive bonding layer. The bonding layer 13 may be a bonding sheet or a metal layer such as an aluminum alloy layer. In particular, when the cooling plate 14 is fabricated from a metal matrix composite (MMC) such as SiSiCTi, the cooling plate 14 is preferably bonded to the bottom surface 12b of the ceramic plate 12 by TCB (Thermal Compression Bonding). TCB refers to a known method involving sandwiching a metal bonding material between two members that are bonding objects and pressing together while heating the two members to a temperature below a solidus temperature of the metal bonding material. Examples of the metal bonding material include aluminum alloys.

The plug placement hole 16 is a hole that penetrates the ceramic plate 12 from the bottom surface 12b to the top surface 12a. The plug placement hole 16 functions as a gas passage from the bottom surface 12b to the top surface 12a (in particular, the reference surface 12f) of the ceramic plate 12. One plug placement hole 16 may be provided, but a plurality of plug placement holes 16 are preferably provided as shown in FIG. 1. While 36 plug placement holes 16 are shown in FIG. 1, the number of plug placement holes 16 is not limited thereto. The gas passage plug 18 is embedded in each plug placement hole 16.

While an opening diameter in a horizontal direction of the plug placement hole 16 (meaning an equivalent diameter if a cross-section of the plug placement hole is not circular) is not particularly limited, for example, the opening diameter typically ranges from 1 to 5 mm at any height position and more typically ranges from 3 to 4 mm. The diameter of the plug placement hole 16 may be constant or may vary from the bottom surface 12b to the top surface 12a (in particular, the reference surface 12f) of the ceramic plate 12. As shown in FIG. 2, preferably, the plug placement hole 16 has a tapered inner circumferential surface that tapers in diameter from top to bottom, with an upper opening area being larger than a lower opening area. Due to the plug placement hole 16 having such a tapered inner circumferential surface, the gas passage plug 18 is more likely to stop at a predetermined height position of the plug placement hole 16 when embedding the gas passage plug 18 into the plug placement hole 16 by press-fitting. Therefore, the gas passage plug 18 can be embedded into the plug placement hole 16 with a high positioning accuracy. In addition, since the gas passage plug 18 is difficult to remove downward but relatively easy to remove upward, there is another advantage of facilitating replacement of the gas passage plug 18. Furthermore, since creepage distance increases, an effect of suppressing electrical discharge is also expected. Therefore, the plug placement hole 16 preferably has a truncated cone-shape or a truncated pyramid-shape.

The gas passage plug 18 is press-fitted into the plug placement hole 16 and is configured to allow gas to pass therethrough. The gas passage plug 18 may be a dense plug composed of a dense body having an internal gas flow path 26 or a porous plug composed of a porous body. In any case, the gas passage plug 18 preferably has a shape adapted to the plug placement hole 16 to enable embedding into the plug placement hole 16 by press-fitting. A top surface of the gas passage plug 18 is preferably at a same height as the reference surface 12f of the ceramic plate 12. A bottom surface of the gas passage plug 18 may be covered with a conductive coating layer 34 which may form a part of a conductive gas passage portion 30 to be described later. The coating layer 34 may be a conductive porous layer. The bottom surface of the gas passage plug 18 may be positioned higher than the bottom surface 12b of the ceramic plate 12, positioned at the same height as the bottom surface 12b, or positioned lower than the bottom surface 12b.

The gas passage plug 18 shown in FIGS. 1 and 2 is a dense plug composed of a dense body having the internal gas flow path 26. In the present specification, a dense body shall refer to a portion of the gas passage plug 18 of which a degree of porosity, as measured in accordance with JIS R 1634:1998, is 5% or less.

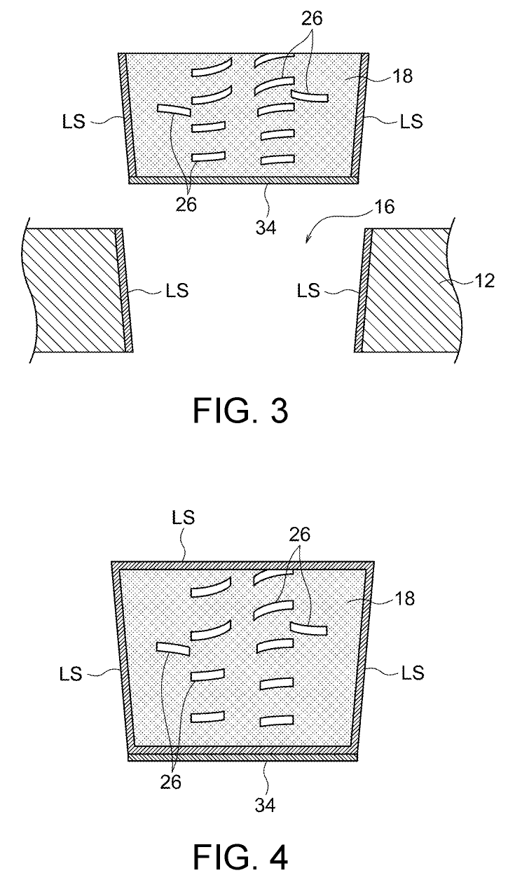

The internal gas flow path 26 is a flow path that allows flow of gas between the top surface and the bottom surface of the gas passage plug 18 as a dense plug. The internal gas flow path 26 is preferably a passage that penetrates inside the dense plug while bending from the bottom surface to the top surface and, for example, may be a zigzag-shaped passage as shown in FIG. 2 or a spiral-shaped passage as shown in FIGS. 3 and 4. The internal gas flow path 26 may be a straight through-hole along the up-down direction. A diameter of a cross-section of the internal gas flow path 26 preferably ranges from 0.1 to 1 mm. One dense plug may have a plurality of internal gas flow paths 26. A degree of porosity, as measured in accordance with JIS R 1634:1998, of a dense portion of the dense plug is preferably less than 1% and more preferably less than 0.1%. The gas passage plug 18 as a dense plug is fixed by being press-fitted into the plug placement hole 16. As the dense plug, for example, ceramics such as alumina and aluminum nitride can be used. The dense plug may be manufactured by firing a molded body formed using, for example, a 3D printer, or by firing a mold-cast molded body.

Alternatively, the gas passage plug 18 may be a porous plug composed of a porous body. In the case of a porous plug, the internal gas flow path 26 described earlier need not be formed and an open pore structure of the porous body itself allows flow of gas between the top surface and the bottom surface of the gas passage plug 18. Typical examples of the porous plug include a porous bulk body obtained by sintering ceramic particles. Examples of the ceramic constituting the porous plug include alumina and aluminum nitride. A degree of porosity, as measured in accordance with the mercury intrusion method specified in JIS R 1655:2003, of the porous plug is preferably 30% or more and an average pore diameter is preferably 20 μm or more. A degree of porosity of the porous plug may be 70% or less. In addition, using porous plating, the coating layer 34 may be formed on a bottom surface of the porous plug as a metallic porous layer.

The gas introduction passage 20 is a passage for introducing gas which is provided in the cooling plate 14 and communicated with the plug placement hole 16. A configuration of the gas introduction passage 20 is not particularly limited as long as the gas introduction passage 20 passes through the inside of the cooling plate 14 and is capable of introducing gas to the plug placement hole 16 and, for example, as shown in FIG. 2, the gas introduction passage 20 may include a longitudinal hole extending in a longitudinal direction within the cooling plate 14 and a lateral hole communicating with the longitudinal hole and extending in a lateral direction within the cooling plate 14. In a mode including the bonding layer 13, the gas introduction passage 20 may also include a bonding layer through-hole 13a provided in the bonding layer 13 as a part of a gas passage in addition to the gas passage provided in the cooling plate 14. In a similar manner, in a mode having the coating layer 34, a coating layer through-hole 34a provided in the coating layer 34 may also form a part of a gas passage. In this manner, the gas introduction passage 20 is configured to pass through the cooling plate 14, the coating layer 34 (when present), and the bonding layer 13 (when present) and to be capable of introducing gas to the plug placement hole 16.

A side surface of at least one of the gas passage plug 18 and the plug placement hole 16 is composed of a low secondary electron emission coefficient (SEEC) material LS having an SEEC of 5.0 or lower. As shown in FIG. 3, both the side surface of the gas passage plug 18 and the side surface of the plug placement hole 16 may be constituted of the low-SEEC material LS. The SEEC of the low-SEEC material LS is 5.0 or lower, preferably 2.0 or lower, and more preferably 1.0 or lower. In particular, when the SEEC is lower than 1.0, since the ceramic plate 12 and the gas passage plug 18 are oriented to absorb secondary electrons, theoretically, no discharge occurs. Even if not so, since applying a low-SEEC material with a SEEC of 5.0 or lower and preferably 2.0 or lower to a side surface portion of the gas supply portion where creeping discharge may occur reduces the likelihood of electron avalanches attributable to high SEEC, discharge voltage increases and, consequently, the occurrence of creeping discharge in the gas supply portion (in other words, the plug placement hole 16 to which the gas passage plug 18 is fixed) can be suppressed. Examples of the low-SEEC material include TiN (SEEC: 1.3), aluminum (SEEC: 1.0), brass (SEEC: 1.5), SiO₂ (SEEC: 2.0), and Cr₂O₃ (SEEC: 1.2), which may be used alone or in combination.

As describe earlier, the secondary electron emission coefficient (SEEC) is defined as a ratio of the number of secondary electrons emitted from a sample to the number of electrons (primary electrons) incident on the sample. The SEEC can be measured according to known procedures described in, for example, Non-Patent Literature 1 (Sawa Araki, "Secondary Electron Emission Coefficient Measurement Technique with Scanning Auger Microprobe", Journal of Surface Analysis, Vol.11, No.2 (2004), pp.71-76). At this point, preferably, primary electron energy is set to 3000 eV and measurements are performed within a bias voltage range of 120 V or lower.

A method of constructing the side surface of the gas passage plug 18 and/or the side surface of the plug placement hole 16 with the low-SEEC material LS is not particularly limited. For example, the side surface of the gas passage plug 18 and/or the side surface of the plug placement hole 16 may be coated with the low-SEEC material LS or a low-SEEC material may be created by applying surface modification to the side surface of the gas passage plug 18 and/or the side surface of the plug placement hole 16. Therefore, the side surface of at least one of the gas passage plug 18 and the plug placement hole 16 preferably includes a coating film and/or a surface modification film of a low-SEEC material. Examples of a method of surface modification for lowering the SEEC include sputtering and plasma CVD.

As shown in FIG. 4, at least one of the top surface and the bottom surface of the gas passage plug 18 may be constituted of the low-SEEC material LS. Accordingly, abnormal discharges including creeping discharges can be more effectively suppressed. In this case, the top surface and/or the bottom surface of the gas passage plug 18 may be coated with a low-SEEC material or a low-SEEC material may be created by applying surface modification to the top surface and/or the bottom surface of the gas passage plug 18. In other words, at least one of the top surface and the bottom surface of the gas passage plug 18 preferably includes a coating film and/or a surface modification film of a low-SEEC material.

Typically, no adhesive is present between the plug placement hole 16 and the gas passage plug 18. In other words, since the gas passage plug 18 is fixed in the plug placement hole 16 by press-fitting, there is no need to interpose an adhesive between the plug placement hole 16 and the gas passage plug 18. In other words, to assist fixation of the gas passage plug 18 in the plug placement hole 16 by press-fitting, an adhesive may be partially present between the plug placement hole 16 and the gas passage plug 18. In this case, a portion which is free of the adhesive on the side surface of at least one of the gas passage plug 18 and the plug placement hole 16 is preferably composed of a low-SEEC material. Since creeping discharge is less likely to occur at locations where the adhesive is present between the plug placement hole 16 and the gas passage plug 18, it is sufficient to construct the remaining areas using a low-SEEC material.

The electrostatic chuck assembly 10 may further include the conductive gas passage portion 30. The conductive gas passage portion 30 is configured in the gas introduction passage 20 so as to be in contact with the bottom surface of the gas passage plug 18, to be electrically connected to the cooling plate 14, and to allow passage of gas between the gas passage plug 18 and the gas introduction passage 20. Accordingly, compared to a case where a porous member with insulation properties is present on a side of the bottom surface of the gas passage plug 18, a potential difference is less likely to occur around an end portion of the gas passage plug 18 on the side of the cooling plate 14. In other words, since a current can be dissipated to the conductive cooling plate 14 via the conductive gas passage portion 30, discharge around the end portion of the gas passage plug 18 on the side of the cooling plate 14 can be suppressed. The conductive gas passage portion 30 preferably includes a leaf spring 32 that biases the gas passage plug 18 upward, and more preferably includes the conductive coating layer 34 that covers the bottom surface of the gas passage plug 18 as described earlier. Since the leaf spring 32 biases the gas passage plug 18 upward using an elastic force, it becomes easier to secure electrical continuity from a contact point of the conductive gas passage portion 30 with the gas passage plug 18 to the cooling plate 14.

The leaf spring 32 is a conductive elastic member that biases and presses the gas passage plug 18 upward using an elastic force. The leaf spring 32 is preferably made of a metallic material, and examples of the metallic material include: Al, Ti, Mo, or alloys thereof; steel; stainless steel (for example, SUS316L); and Hastelloy®. The leaf spring 32 may be manufactured, for example, by bending a metal plate. While the leaf spring 32 in the illustrated example has a zigzag shape formed by bending a metal plate, the leaf spring 32 is not limited to this shape and may have various shapes as long as the desired function is secured.

The coating layer 34 covers the bottom surface of the gas passage plug 18 and, accordingly, the coating layer 34 is in contact with the bottom surface of the gas passage plug 18. When the gas passage plug 18 is a dense plug, the coating layer 34 is preferably formed as a dense layer and, in such a case, the coating layer 34 preferably has a coating layer through-hole 34a in which gas is permeable in the up-down direct12ion. The coating layer through-hole 34a communicates an opening of the internal gas flow path 26 on the bottom surface of the gas passage plug 18 and the gas introduction passage 20. For example, the coating layer 34 can be manufactured in advance by forming, by sputtering, electroless plating, or the like, the coating layer 34 on the bottom surface of the gas passage plug 18 prior to press-fitting the gas passage plug 18 into the ceramic plate 12, and then opening a hole 34a. The coating layer 34 is preferably made of a metallic material, and examples of the metallic material include metals with excellent corrosion resistance such as Au, Ag, Al, Ti, stainless steel (for example, SUS316L), and Hastelloy (a Ni-Fe-Mo alloy; Hastelloy is a registered trademark). When the gas passage plug 18 is a porous plug, the coating layer 34 may be a conductive porous layer. In this case, using porous plating, the coating layer 34 may be formed on the bottom surface of the gas passage plug 18 as a metallic porous layer.

### Reference Signs List

10, 110: electrostatic chuck assembly, 12, 112: ceramic plate, 12a: top surface, 12b: bottom surface, 12d: sealing band, 12e: small circular protrusion, 12f: reference surface, 13, 113: bonding layer, 13a: bonding layer through-hole, 14, 114: cooling plate, 16, 116: plug placement hole, 18, 118: gas passage plug, 20, 120: gas introduction passage, 22: internal electrode, 24: refrigerant flow path, 26: internal gas flow path, 30: conductive gas passage portion, 32: leaf spring, 34: coating layer, 34a: coating layer through-hole, 115: gas inlet hole, 117: insulating tube, W: wafer, P: plasma, D: creeping discharge, LS: low-SEEC material

What is claimed is:

1. An electrostatic chuck assembly, comprising: a ceramic plate having a top surface on which a wafer is to be placed and a bottom surface facing the top surface and incorporating an internal electrode that is an ESC electrode and/or an RF electrode; a cooling plate mounted to the bottom surface of the ceramic plate; a plug placement hole penetrating the ceramic plate from the bottom surface to the top surface; a gas passage plug press-fitted into the plug placement hole and configured to allow gas to pass therethrough; and a gas introduction passage provided in the cooling plate and communicating with the plug placement hole, wherein a side surface of at least one of the gas passage plug and the plug placement hole is composed of a low secondary electron emission coefficient (SEEC) material having an SEEC of 5.0 or lower.

2. The electrostatic chuck assembly according to claim 1, wherein the secondary electron emission coefficient (SEEC) is 2.0 or lower.

3. The electrostatic chuck assembly according to claim 1, wherein the low-SEEC material includes at least one selected from the group consisting of TiN, Al, brass, SiO₂ and Cr₂O₃.

4. The electrostatic chuck assembly according to claim 1, wherein a side surface of at least one of the gas passage plug and the plug placement hole includes a coating film and/or a surface modification film of the low-SEEC material.

5. The electrostatic chuck assembly according to claim 1, wherein at least one of a top surface and a bottom surface of the gas passage plug is composed of the low-SEEC material.

6. The electrostatic chuck assembly according to claim 5, wherein at least one of the top surface and the bottom surface of the gas passage plug includes a coating film and/or a surface modification film of the low-SEEC material.

7. The electrostatic chuck assembly according to claim 1, wherein an interface between the plug placement hole and the gas passage plug is free of an adhesive.

8. The electrostatic chuck assembly according to claim 1, wherein an adhesive is partially present between the plug placement hole and the gas passage plug, and a portion which is free of the adhesive on a side surface of at least one of the gas passage plug and the plug placement hole is composed of the low-SEEC material.

9. The electrostatic chuck assembly according to claim 1, wherein the gas passage plug is composed of a dense body having an internal gas flow path.

10. The electrostatic chuck assembly according to claim 1, wherein the gas passage plug is composed of a porous body.

11. The electrostatic chuck assembly according to claim 1, further comprising, in the gas introduction passage, a conductive gas passage portion in contact with a bottom surface of the gas passage plug, electrically connected to the cooling plate, and allowing passage of gas between the gas passage plug and the gas introduction passage.

12. The electrostatic chuck assembly according to claim 11, wherein the conductive gas passage portion includes a leaf spring that biases the gas passage plug upward.
